(19) United States
(12) Patent Application Publication
(10) Pub. No.: US 2025/0031492 A1
(43) Pub. Date: Jan. 23, 2025

(54) WINDOW AND DISPLAY DEVICE INCLUDING THE SAME

(71) Applicant: Samsung Display Co., LTD., Yongin-si (KR)

(72) Inventors: SEUNGMIN SONG, Yongin-si (KR); HYE-JIN OH, Yongin-si (KR); DONGHEE LEE, Yongin-si (KR); JONGKAP JO, Yongin-si (KR); KYUHYEONG CHEON, Yongin-si (KR); SEOYOUNG CHOI, Yongin-si (KR)

(21) Appl. No.: 18/663,572

(22) Filed: May 14, 2024

(30) Foreign Application Priority Data
Jul. 17, 2023 (KR) 10-2023-0092301

(51) Int. Cl. H01L 33/44; H01L 25/075

(52) U.S. Cl. CPC H01L 33/44; H01L 25/0753

(57) ABSTRACT

Embodiments provide a window and a display device including the window. The window includes a substrate; at least one light control layer disposed on the substrate and, which controls light having a wavelength of about 280 nm or less; and a coating layer disposed on the at least one light control layer.

This application claims priority to Korean Patent Application No. 10-2023-0092301, filed on Jul. 17, 2023, and all the benefits accruing therefrom under 35 U.S.C. § 119, the content of which in its entirety is herein incorporated by reference.

### BACKGROUND

### 1. Field

Embodiments relate to a window. More specifically, embodiments relate to a window and a display device including the window.

### 2. Description of the Related Art

A display device includes a display panel that generates and displays an image, and a window disposed on the display panel and covers the display panel. The window may transmit the image displayed on the display panel and provide it to a viewer. In addition, the window may protect the display panel from external impact. Generally, the window may include a glass substrate, a sapphire substrate, a plastic film, or the like.

### SUMMARY

Embodiments provide a window with improved reliability.

Embodiments provide a display device including the window.

A window according to an embodiment of the present disclosure includes: a substrate; at least one light control layer disposed on the substrate and, which controls light having a wavelength of about 280 nanometers (nm) or less; and a coating layer disposed on the at least one light control layer.

In an embodiment, the at least one light control layer may include: at least one light absorption layer disposed on the substrate and, which absorbs the light having the wavelength of about 280 nm or less; and at least one refractive layer disposed on the substrate.

In an embodiment, the at least one light absorption layer may include at least one of benzotriazole, triazine, benzimidazole, ZnO, and TiO2.

In an embodiment, the at least one refractive layer may include at least one of MgF2, CaF2, BaF2, LiF, and CeF3.

In an embodiment, a thickness of each of the at least one refractive layer may be about 50 nm to about 100 nm.

In an embodiment, one of the at least one light absorption layer may be disposed between the substrate and the at least one refractive layer.

In an embodiment, the at least one refractive layer may be disposed between the substrate and one of the at least one light absorption layer.

In an embodiment, the substrate may be a sapphire substrate.

In an embodiment, the sapphire substrate may be doped with a dopant.

In an embodiment, the dopant may include at least one of Ti, Co, Cr, Fe, and Cu.

In an embodiment, the window may further include an inorganic layer disposed between the substrate and the coating layer.

A display device according to an embodiment of the present disclosure includes: a display panel including at least one light emitting element; a substrate disposed on the display panel; at least one light control layer disposed on the substrate and, which controls light having a wavelength of about 280 nm or less; and a coating layer disposed on the at least one light control layer.

In an embodiment, the at least one light control layer may include: at least one light absorption layer disposed on the substrate and, which absorbs the light having the wavelength of about 280 nm or less; and at least one refractive layer disposed on the substrate.

In an embodiment, the at least one light absorption layer may include at least one of benzotriazole, triazine, benzimidazole, ZnO, and TiO2.

In an embodiment, the at least one refractive layer may include at least one of MgF2, CaF2, BaF2, LiF, and CeF3.

In an embodiment, a thickness of each of the at least one refractive layer may be about 50 nm to about 100 nm.

In an embodiment, the substrate may be a sapphire substrate.

In an embodiment, the sapphire substrate may be doped with a dopant.

In an embodiment, the dopant may include at least one of Ti, Co, Cr, Fe, and Cu.

In an embodiment, the display device may further include an inorganic layer disposed between the substrate and the coating layer.

In an embodiment, the display device may further include an adhesive layer disposed between the display panel and the substrate.

In a display device according to embodiments of the present disclosure, the display device may include: a display panel, a window, and an adhesive layer disposed between the display panel and the window. The window may include a light control layer. The light control layer may absorb light in an Ultraviolet-C (UV-C) region, and may refract light in the UV-C region. Accordingly, light in the UV-C region that reaches the adhesive layer through the window may be blocked. Therefore, since problems such as bubbles inside the adhesive layer, a decrease in adhesion of the adhesive layer, or the like, which may be caused by light in the UV-C region, may be prevented, a display quality of the display device may be effectively improved.

### BRIEF DESCRIPTION OF THE DRAWINGS

FIG. 1 is a plan view illustrating a display device according to an embodiment of the present disclosure.

FIG. 2 is a cross-sectional view illustrating the display device of FIG. 1.

FIGS. 3, 4, 5, 6, and 7 are cross-sectional views illustrating a window included in the display device of FIG. 1.

FIG. 8 is a cross-sectional view illustrating a display panel included in the display device of FIG. 1.

FIG. 9 is a cross-sectional view illustrating a window included in a display device according to another embodiment of the present disclosure.

FIG. 10 is a cross-sectional view illustrating a window included in a display device according to still another embodiment of the present disclosure.

### DETAILED DESCRIPTION

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element or “connected to” another element, it can be directly on or directly connected to the other element or intervening elements may be present therebetween. In contrast, when an element is referred to as being “directly on” another element, there are no intervening elements present.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +10% or 5% of the stated value. Hereinafter, embodiments of the present disclosure will be described in more detail with reference to the accompanying drawings. The same reference numerals are used for the same components in the drawings, and redundant descriptions of the same components will be omitted.

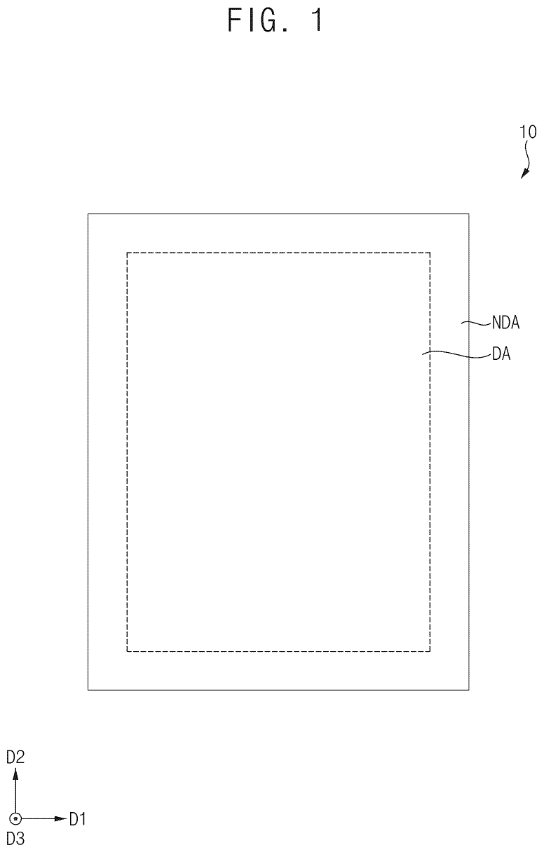

FIG. 1 is a plan view illustrating a display device according to an embodiment of the present disclosure.

Referring to FIG. 1, a display device 10 according to an embodiment of the present disclosure may include a display area DA and a non-display area NDA.

The display area DA may be an area that displays an image. In the display area DA, a plurality of pixels may be repeatedly arranged along a first direction D1 and a second direction D2 intersecting the first direction D1 in a plan view. For example, the second direction D2 may be perpendicular to the first direction D1. Each of the pixels may be defined as a minimum light emitting unit that displays light.

Signal lines such as a gate line, a data line, or the like may be disposed in the display area DA. The signal lines may be connected to each of the pixels. Each of the pixels may receive a gate signal, a data signal, or the like from the signal lines. Accordingly, an image may be displayed in the display area DA in a third direction D3 intersecting each of the first direction D1 and the second direction D2. For example, the third direction D3 may be perpendicular to each of the first direction D1 and the second direction D2.

The non-display area NDA may be an area that does not display an image. The non-display area NDA may be disposed around the display area DA. In an embodiment, for example, the non-display area NDA may surround the entirety of the display area DA. Drivers for displaying an image of the display area DA may be disposed in the non-display area NDA.

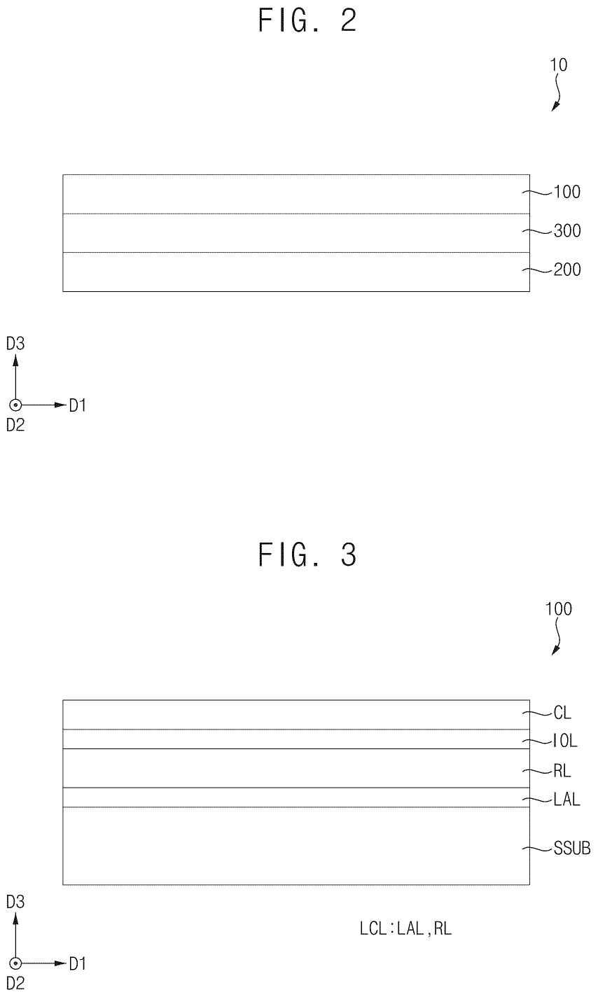

FIG. 2 is a cross-sectional view illustrating the display device of FIG. 1.

Referring to FIGS. 1 and 2, the display device 10 may include a display panel 200, a window 100, and an adhesive layer 300.

The display panel 200 may include the pixels to display an image. The display panel 200 may emit light toward an upper surface (i.e., in the third direction D3) to display an image.

The window 100 may be disposed on the display panel 200. The window 100 may cover the upper surface of the display panel 200. The window 100 may block foreign substances penetrating from outside, and may prevent the display panel 200 from being damaged or malfunctioned by external impacts. The window 100 may be optically transparent. Accordingly, the window 100 may transmit light emitted from the display panel 200.

The adhesive layer 300 may be disposed between the display panel 200 and the window 100. The adhesive layer 300 may adhere the display panel 200 and the window 100 to each other. In an embodiment, for example, the adhesive layer 300 may include a pressure sensitive adhesive (“PSA”), an optically clear adhesive (“OCA”), an optically clear resin (“OCR”), or the like.

In an embodiment, at least one functional coating layer may be further disposed between the display panel 200 and the window 100. The functional coating layer may include a single layer or multiple layers. The functional coating layer may include an optical coating layer for improving visibility of the display device 10, a primer coating layer for improving adhesion between the display panel 200 and the window 100, a high-strength coating layer for improving impact resistance of the display device 10, or the like.

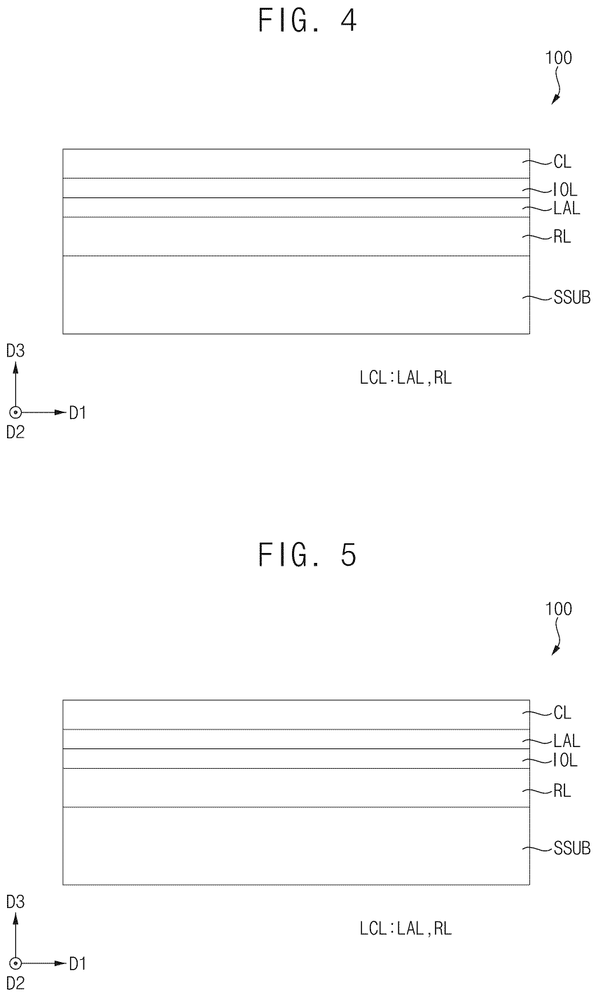

FIGS. 3, 4, 5, 6, and 7 are cross-sectional views illustrating a window included in the display device of FIG. 1.

Referring to FIGS. 2, 3, 4, 5, 6, and 7, the window 100 may include a base substrate SSUB, a light control layer LCL, an inorganic layer IOL, and a coating layer CL.

The base substrate SSUB may function as a body of the window 100. In an embodiment, for example, the base substrate SSUB may include glass, sapphire, plastic, or the like. In an embodiment, the base substrate SSUB may be a sapphire substrate. When the base substrate SSUB is a sapphire substrate, a transmittance of the base substrate SSUB to light having a wavelength of about 280 nanometers (nm) or less, specifically about 100 nm to about 280 nm, and more specifically about 200 nm to about 250 nm, may be relatively high. In an embodiment, for example, the base substrate SSUB may transmit light in an Ultraviolet-C (UV-C) region. Accordingly, light in the UV-C region may reach the adhesive layer 300 through the window 100.

In another embodiment, the base substrate SSUB may be a sapphire substrate doped with a dopant. The dopant may be a transition metal with a relatively small size. In an embodiment, for example, the dopant may include at least one of titanium (Ti), cobalt (Co), chromium (Cr), iron (Fe), and copper (Cu), but the present disclosure is not limited thereto. The base substrate SSUB may be formed from a sapphire melt including the dopant in another embodiment. When the base substrate SSUB is a doped sapphire substrate, a transmittance of the base substrate SSUB to light having a wavelength of about 280 nm or less, specifically about 100 nm to about 280 nm, and more specifically about 200 nm to about 250 nm, may be relatively low. In an embodiment, for example, the base substrate SSUB may block light in the UV-C region. Accordingly, light in the UV-C region that reaches the adhesive layer 300 through the window 100 may be blocked.

The light control layer LCL may be disposed on the base substrate SSUB. In an embodiment, the light control layer LCL may control light having a wavelength of about 280 nm or less, specifically about 100 nm to about 280 nm, and more specifically about 200 nm to about 250 nm. The light control layer LCL may include a light absorption layer LAL and a refractive layer RL.

The light absorption layer LAL may be disposed on the base substrate SSUB. The light absorption layer LAL may absorb light having a specific wavelength range. In an embodiment, the light absorption layer LAL may absorb light having a wavelength of about 280 nm or less, specifically about 200 nm to about 280 nm, more specifically about 200 nm to about 250 nm. In an embodiment, for example, the light absorption layer LAL may absorb light in the UV-C region. That is, the light absorption layer LAL may prevent light in the UV-C region from transmitting through the base substrate SSUB. Accordingly, light in the UV-C region that reaches the adhesive layer 300 through the window 100 may be blocked.

In an embodiment, the light absorption layer LAL may include at least one of benzotriazole, triazine, benzimidazole, ZnO, and TiO₂. However, the present disclosure is not limited thereto, and the light absorption layer LAL may include various materials that absorb light having a wavelength of about 280 nm or less, specifically about 100 nm to about 280 nm, and more specifically about 200 nm to about 250 nm.

The light absorption layer LAL may have a relatively thin thickness. Accordingly, a stacking order of the light absorption layer LAL may be variously changed. In an embodiment, the light absorption layer LAL may be disposed between the base substrate SSUB and the refractive layer RL (see FIG. 3). In another embodiment, the light absorption layer LAL may be disposed between the refractive layer RL and the inorganic layer IOL (see FIG. 4). In still another embodiment, the light absorption layer LAL may be disposed between the inorganic layer IOL and the coating layer CL (see FIG. 5).

In an embodiment, there may be a plurality of light absorption layers LAL. When there are a plurality of light absorption layers LAL, the light absorption layers LAL may be variously disposed between the base substrate SSUB and the coating layer CL. In an embodiment, for example, one of the light absorption layers LAL may be disposed between the base substrate SSUB and the refractive layer RL, and the other of the light absorption layers LAL may be disposed between the refractive layer RL and the coating layer CL (see FIG. 6). However, the present disclosure is not limited thereto, and a stacking order of the light absorption layers LAL may be variously changed. In addition, in FIG. 6, the window 100 is illustrated as including two light absorption layers LAL, but the present disclosure is not limited thereto. For another example, the window 100 may include three or more light absorption layers LAL, and a stacking order of the light absorption layers LAL may be variously changed.

The refractive layer RL may be disposed on the base substrate SSUB. The refractive layer RL may change a path of light by refracting the light. In an embodiment, for example, the refractive layer RL may include a material having a relatively low refractive index. In an embodiment, the refractive layer RL may refract light having a wavelength of about 280 nm or less, specifically about 100 nm to about 280 nm, and more specifically about 200 nm to about 250 nm. In an embodiment, for example, the refractive layer RL may refract light in the UV-C region. That is, the refractive layer RL may prevent light in the UV-C region from transmitting through the base substrate SSUB. Accordingly, light in the UV-C region that reaches the adhesive layer 300 through the window 100 may be blocked.

In an embodiment, the refractive layer RL may include at least one of MgF₂, CaF₂, BaF₂, LiF, and CeF₃. However, the present disclosure is not limited thereto, and the refractive layer RL may include various materials having a relatively low refractive index for light having a wavelength of about 280 nm or less, specifically about 100 nm to about 280 nm, and more specifically about 200 nm to about 250 nm.

In an embodiment, a thickness of the refractive layer RL may be about 50 nm to about 100 nm. When the thickness of the refractive layer RL is less than about 50 nm, light in the UV-C region may not be sufficiently refracted, and when the thickness of the refractive layer RL is more than about 100 nm, a light transmittance of the window 100 may decrease. However, in the present disclosure, the thickness of the refractive layer RL is not limited thereto.

In an embodiment, there may be a plurality of refractive layers RL. When there are a plurality of refractive layers RL, the refractive layers RL may be variously disposed between the base substrate SSUB and the coating layer CL. In an embodiment, for example, the refractive layers RL may be sequentially disposed on the light absorption layer LAL (see FIG. 7). However, the present disclosure is not limited thereto, and a stacking order of the refractive layers RL may be variously changed. In addition, in FIG. 7, the window 100 is illustrated as including two refractive layers RL, but the present disclosure is not limited thereto. For another example, the window 100 may include three or more refractive layers RL, and a stacking order of the refractive layers RL may be variously changed.

The inorganic layer IOL may be disposed on the refractive layer RL. The inorganic layer IOL may adhere the refractive layer RL and other components to each other, and may increase hardness of the window 100. That is, the inorganic layer IOL may improve adhesion of the refractive layer RL. In an embodiment, for example, the inorganic layer IOL may improve adhesion between the refractive layer RL and the coating layer CL.

In an embodiment, the inorganic layer IOL may include silicon oxide. In an embodiment, for example, the inorganic layer IOL may include SiO₂. However, the present disclosure is not limited thereto, and the inorganic layer IOL may include various materials that improve the adhesion of the refractive layer RL.

In an embodiment, a thickness of the inorganic layer IOL may be about 10 nm to about 20 nm. When the thickness of the inorganic layer IOL is less than 10 nm, the inorganic layer IOL may not sufficiently improve the adhesion of the refractive layer RL, and when the thickness of the inorganic layer IOL is more than 20 nm, the light transmittance of the window 100 may decrease. However, in the present disclosure, the thickness of the inorganic layer IOL is not limited thereto.

In an embodiment, there may be a plurality of inorganic layers IOL. When there are a plurality of inorganic layers IOL, the inorganic layers IOL may be variously disposed between the base substrate SSUB and the coating layer CL. In an embodiment, for example, the inorganic layers IOL may be disposed on the refractive layers RL, respectively (see FIG. 7). However, the present disclosure is not limited thereto, and a stacking order of the inorganic layers IOL may be variously changed. In addition, in FIG. 7, the window 100 is illustrated as including two inorganic layers IOL, but the present disclosure is not limited thereto. For another example, the window 100 may include three or more inorganic layers IOL, and a stacking order of the inorganic layers IOL may be variously changed.

In another embodiment, the inorganic layer IOL may be omitted. That is, the window 100 may not include the inorganic layer IOL.

The coating layer CL may be disposed on the light absorption layer LAL, the refractive layer RL, and the inorganic layer IOL. The coating layer CL may protect a surface of the window 100 by suppressing wear of the surface of the window 100. The coating layer CL may include a fluorine-based polymer. In an embodiment, for example, the coating layer CL may include perfluorinated polyether (“PEPE”). However, the present disclosure is not limited thereto, and the coating layer CL may include various materials that protect the surface of the window 100.

In an embodiment, for example, a thickness of the coating layer CL may be about 20 nm to about 50 nm. When the thickness of the coating layer CL is less than 20 nm, the surface of the window 100 may not be sufficiently protected, and when the thickness of the coating layer CL is more than about 50 nm, the light transmittance of the window 100 may decrease. However, in the present disclosure, the thickness of the coating layer CL is not limited thereto.

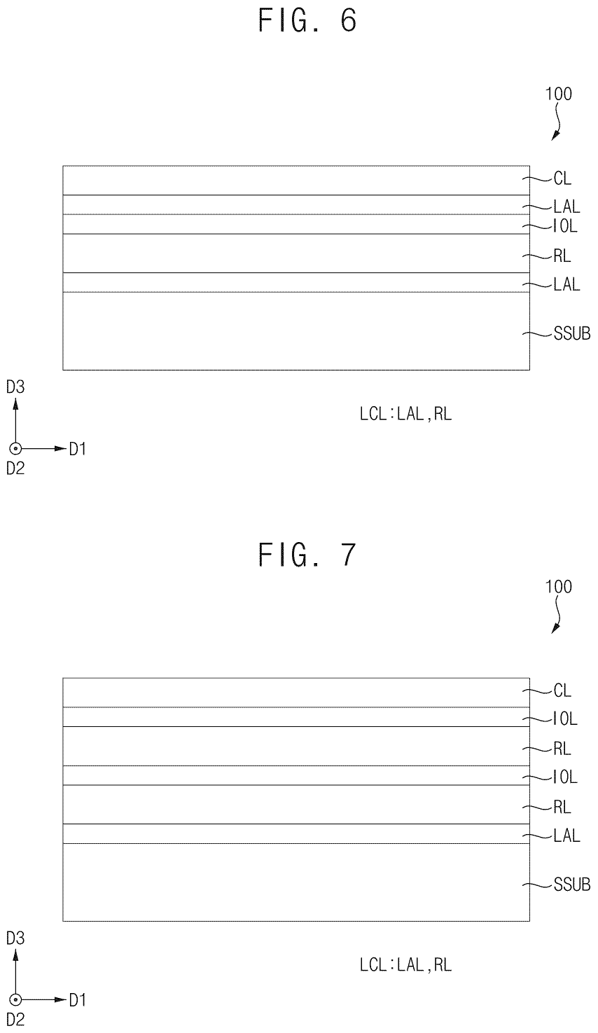

FIG. 8 is a cross-sectional view illustrating the display panel included in the display device of FIG. 1.

Referring to FIG. 8, the display panel 200 may include a substrate SUB, an active pattern ACT, a first insulating layer IL1, a gate electrode GAT, a second insulating layer IL2, a first connection electrode SD1, a second connection electrode SD2, a third insulating layer IL3, a pixel electrode PE, a pixel defining layer PDL, a light emitting layer EL, a common electrode CE, and an encapsulation layer ENC.

The substrate SUB may include a transparent material or an opaque material. The substrate SUB may include glass, quartz, plastic, or the like. These may be used alone or in combination with each other.

The active pattern ACT may be disposed on the substrate SUB. The active pattern ACT may include a source area, a drain area, and a channel area positioned between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (“IGZO”), indium tin zinc oxide (“ITZO”), or the like. These may be used alone or in combination with each other.

The first insulating layer IL1 may be disposed on the substrate SUB, and may cover the active pattern ACT. The first insulating layer IL1 may include an inorganic material such as silicon oxide, silicon nitride, silicon carbide, silicon oxynitride, silicon oxycarbide, or the like. These may be used alone or in combination with each other.

The gate electrode GAT may be disposed on the first insulating layer IL1. The gate electrode GAT may overlap the channel area of the active pattern ACT in a plan view. The gate electrode GAT may include a metal, an alloy, a conductive metal oxide, a metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide, indium zinc oxide, or the like. Examples of the metal nitride may include aluminum nitride (AlNₓ), tungsten nitride (WNₓ), chromium nitride (CrNₓ), or the like. These may be used alone or in combination with each other.

The second insulating layer IL2 may be disposed on the first insulating layer IL1, and may cover the gate electrode GAT. The second insulating layer IL2 may include an inorganic material such as silicon oxide, silicon nitride, silicon carbide, silicon oxynitride, silicon oxycarbide, or the like. These may be used alone or in combination with each other.

The first connection electrode SD1 and the second connection electrode SD2 may be disposed on the second insulating layer IL2. The first connection electrode SD1 may be connected to the source area of the active pattern ACT through a first contact hole penetrating the first insulating layer IL1 and the second insulating layer IL2. In addition, the second connection electrode SD2 may be connected to the drain area of the active pattern ACT through a second contact hole penetrating the first insulating layer IL1 and the second insulating layer IL2. In an embodiment, for example, each of the first connection electrode SD1 and the second connection electrode SD2 may include a metal, an alloy, a conductive metal oxide, a metal nitride, or the like. These may be used alone or in combination with each other.

Accordingly, a transistor TR including the active pattern ACT, the gate electrode GAT, the first connection electrode SD1, and the second connection electrode SD2 may be disposed on the substrate SUB.

The third insulating layer IL3 may be disposed on the second insulating layer IL2. The third insulating layer IL3 may sufficiently cover the first connection electrode SD1 and the second connection electrode SD2. The third insulating layer IL3 may include an organic material such as phenol resin, acrylic resin, polyimide resin, polyamide resin, siloxane resin, epoxy resin, or the like. These may be used alone or in combination with each other.

The pixel electrode PE may be disposed on the third insulating layer IL3. The pixel electrode PE may be connected to the second connection electrode SD2 through a contact hole penetrating the third insulating layer IL3. The pixel electrode PE may include a metal, an alloy, a conductive metal oxide, a metal nitride, or the like. These may be used alone or in combination with each other. In an embodiment, for example, the pixel electrode PE may function as an anode.

The pixel defining layer PDL may be disposed on the third insulating layer IL3. The pixel defining layer PDL may cover at least a portion of the pixel electrode PE. In an embodiment, for example, the pixel defining layer PDL may cover an edge of the pixel electrode PE. That is, an opening exposing at least a portion of an upper surface of the pixel electrode PE may be defined in the pixel defining layer PDL.

The light emitting layer EL may be disposed on the pixel electrode PE. Specifically, the light emitting layer EL may be disposed on the pixel electrode PE exposed by the opening of the pixel defining layer PDL. The light emitting layer EL may include an organic material that emits light of a preset color.

The common electrode CE may be disposed on the light emitting layer EL and the pixel defining layer PDL. The common electrode CE may be a plate electrode. The common electrode CE may include a metal, an alloy, a conductive metal oxide, a metal nitride, or the like. These may be used alone or in combination with each other. In an embodiment, for example, the common electrode CE may function as a cathode.

Accordingly, a light emitting element LE including the pixel electrode PE, the light emitting layer EL, and the common electrode CE may be disposed on the substrate SUB. The light emitting element LE may be electrically connected to the transistor TR. The light emitting element LE may emit light corresponding to a driving current of the transistor TR.

The encapsulation layer ENC may be disposed on the common electrode CE. The encapsulation layer ENC may protect the light emitting element LE from external oxygen and moisture. The encapsulation layer ENC may include at least one inorganic layer and at least one organic layer.

The display device 10 according to an embodiment of the present disclosure may include the window 100 including the light control layer LCL. The light control layer LCL may include the light absorption layer LAL and the refractive layer RL. The light absorption layer LAL may absorb light in the UV-C region, and the refractive layer RL may refract light in the UV-C region. Accordingly, light in the UV-C region that reaches the adhesive layer 300 through the window 100 may be blocked. Therefore, since problems such as bubbles inside the adhesive layer 300, a decrease in the adhesion of the adhesive layer 300, or the like, which may be caused by light in the UV-C region, may be prevented, a display quality of the display device 10 may be effectively improved.

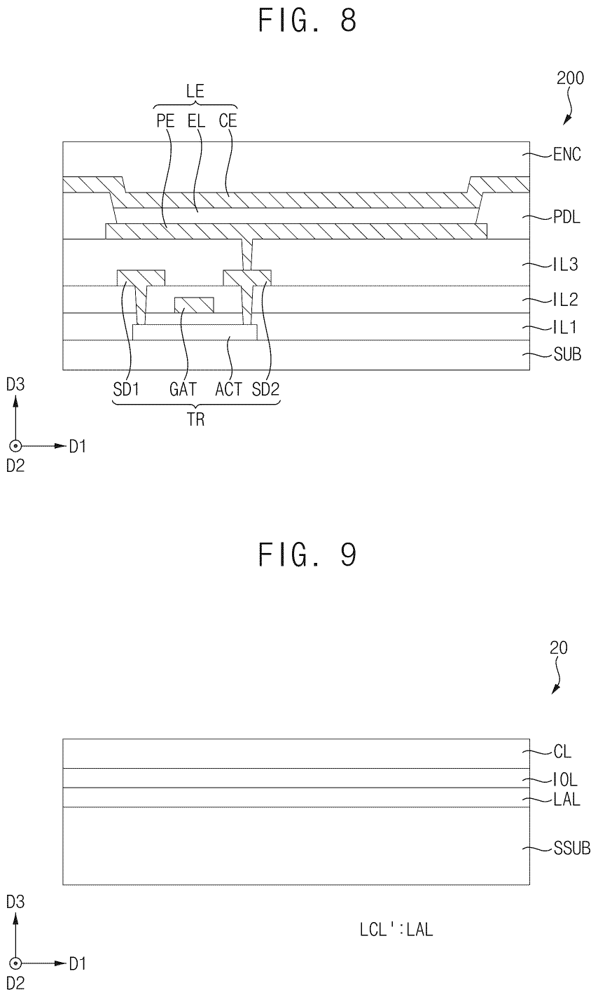

FIG. 9 is a cross-sectional view illustrating a window included in a display device according to another embodiment of the present disclosure.

Hereinafter, descriptions overlapping the window 100 included in the display device 10 described with reference to FIGS. 2, 3, 4, 5, 6, and 7 will be omitted or simplified.

Referring to FIG. 9, a window included in the display device 20 according to another embodiment of the present disclosure may include a base substrate SSUB, a light control layer LCL′, an inorganic layer IOL, and a coating layer CL.

In an embodiment, the base substrate SSUB may be a sapphire substrate. In this case, a transmittance of the base substrate SSUB to light having a wavelength of about 280 nm or less, specifically about 100 nm to about 280 nm, and more specifically about 200 nm to about 250 nm, may be relatively high. In an embodiment, for example, the base substrate SSUB may transmit light in an UV-C region.

The light control layer LCL′ may be disposed on the base substrate SSUB. In an embodiment, the light control layer LCL′ may control light having a wavelength of about 280 nm or less, specifically about 100 nm to about 280 nm, and more specifically about 200 nm to about 250 nm. The light control layer LCL′ may include a light absorption layer LAL.

In an embodiment, the light absorption layer LAL may absorb light having a wavelength of about 280 nm or less, specifically about 100 nm to about 280 nm, and more specifically about 200 nm to about 250 nm. In an embodiment, for example, the light absorption layer LAL may absorb light in the UV-C region, and may prevent light in the UV-C region from transmitting through the base substrate SSUB. Accordingly, light in the UV-C region that reaches an adhesive layer disposed below the window through the window may be blocked. In an embodiment, the light absorption layer LAL may include at least one of benzotriazole, triazine, benzimidazole, ZnO, and TiO₂, but the present disclosure is not limited thereto.

The inorganic layer IOL may be disposed on the light absorption layer LAL. The inorganic layer IOL may adhere the light absorption layer LAL and other components to each other to increase hardness of the window. In an embodiment, for example, the inorganic layer IOL may improve adhesion between the light absorption layer LAL and the coating layer CL. In an embodiment, the inorganic layer IOL may be omitted, and the window of the display device 20 may not include the inorganic layer IOL.

In FIG. 9, the window is illustrated as including one light absorption layer LAL and one inorganic layer IOL, but the present disclosure is not limited thereto. For another example, the window may include two or more light absorption layers LAL or two or more inorganic layers IOL, and a stacking order of the light absorption layers LAL and the inorganic layers IOL may be variously changed.

The display device 20 according to another embodiment of the present disclosure may include the window including the light control layer LCL′. The light control layer LCL′ may absorb light in the UV-C region. Accordingly, light in the UV-C region that transmits through the base substrate SSUB and reaches the adhesive layer through the window may be blocked. Therefore, since problems such as bubbles inside the adhesive layer, a decrease in adhesion of the adhesive layer, or the like, which may be caused by light in the UV-C region, may be prevented, a display quality of the display device 20 may be effectively improved.

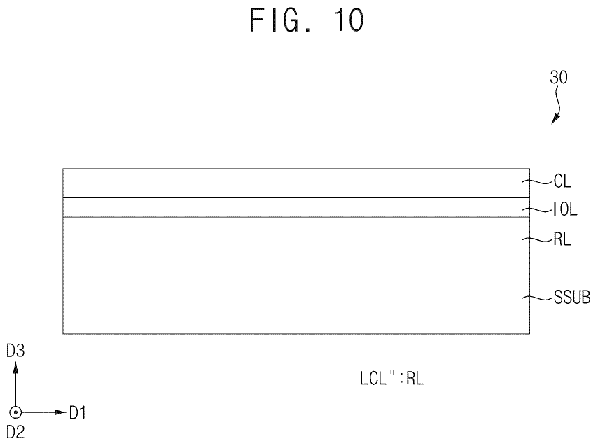

FIG. 10 is a cross-sectional view illustrating a window included in a display device according to still another embodiment of the present disclosure.

Hereinafter, descriptions overlapping the window 100 included in the display device 10 described with reference to FIGS. 2, 3, 4, 5, 6, and 7 will be omitted or simplified.

Referring to FIG. 10, a window included in a display device 30 according to still another embodiment of the present disclosure may include a base substrate SSUB, a light control layer LCL″, an inorganic layer IOL, and a coating layer CL.

In an embodiment, the base substrate SSUB may be a sapphire substrate. In this case, a transmittance of the base substrate SSUB to light having a wavelength of about 280 nm or less, specifically about 100 nm to about 280 nm, and more specifically about 200 nm to about 250 nm may be relatively high. In an embodiment, for example, the base substrate SSUB may transmit light in an UV-C region.

The light control layer LCL″ may be disposed on the base substrate SSUB. In an embodiment, the light control layer LCL″ may control light having a wavelength of about 280 nm or less, specifically about 100 nm to about 280 nm, and more specifically about 200 nm to about 250 nm. The light control layer LCL″ may include a refractive layer RL.

The refractive layer RL may be disposed on the base substrate SSUB. In an embodiment, the refractive layer RL may refract light having a wavelength of about 280 nm or less, specifically about 100 nm to about 280 nm, and more specifically about 200 nm to about 250 nm. In an embodiment, for example, the refractive layer RL may refract light in the UV-C region, and may prevent light in the UV-C region from transmitting through the base substrate SSUB. Accordingly, light in the UV-C region that reaches an adhesive layer disposed below the window through the window may be blocked. In an embodiment, the refractive layer RL may include at least one of MgF₂, CaF₂, BaF₂, LiF, and CeF₃, but the present disclosure is not limited thereto.

The inorganic layer IOL may be disposed on the refractive layer RL. The inorganic layer IOL may adhere the refractive layer RL and other components to each other to increase hardness of the window. In an embodiment, for example, the inorganic layer IOL may improve adhesion between the refractive layer RL and the coating layer CL. In an embodiment, the inorganic layer IOL may be omitted, and the window of the display device 30 may not include the inorganic layer IOL.

In FIG. 10, the window is illustrated as including one refractive layer RL and one inorganic layer IOL, but the present disclosure is not limited thereto. For another example, the window may include two or more refractive layers RL or two or more inorganic layers IOL, and a stacking order of the refractive layers RL and the inorganic layers IOL may be variously changed.

The display device 30 according to still another embodiment of the present disclosure may include the window including the light control layer LCL″. The light control layer LCL″ may refract light having a wavelength of about 280 nm or less, specifically about 100 nm to about 280 nm, and more specifically about 200 nm to about 250 nm. Accordingly, light in the UV-C region that transmits through the base substrate SSUB and reaches the adhesive layer through the window may be blocked. Therefore, since problems such as bubbles inside the adhesive layer, a decrease in adhesion of the adhesive layer, or the like, which may be caused by light in the UV-C region, may be prevented, a display quality of the display device 30 may be effectively improved.

The present disclosure can be applied to a manufacturing process of various display devices. In an embodiment, for example, the present disclosure is applicable to a manufacturing process of various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A window comprising:
a substrate;
at least one light control layer disposed on the substrate and, which controls light having a wavelength of about 280 nanometers (nm) or less; and
a coating layer disposed on the at least one light control layer.

2. The window of claim 1, wherein the at least one light control layer includes:
at least one light absorption layer disposed on the substrate and, which absorbs the light having the wavelength of about 280 nm or less; and
at least one refractive layer disposed on the substrate.

3. The window of claim 2, wherein the at least one light absorption layer includes at least one of benzotriazole, triazine, benzimidazole, ZnO, and TiO₂.

4. The window of claim 2, wherein the at least one refractive layer includes at least one of MgF₂, CaF₂, BaF₂, LiF, and CeF₃.

5. The window of claim 2, wherein a thickness of each of the at least one refractive layer is about 50 nm to about 100 nm.

6. The window of claim 2, wherein one of the at least one light absorption layer is disposed between the substrate and the at least one refractive layer.

7. The window of claim 2, wherein the at least one refractive layer is disposed between the substrate and one of the at least one light absorption layer.

8. The window of claim 1, wherein the substrate is a sapphire substrate.

9. The window of claim 8, wherein the sapphire substrate is doped with a dopant.

10. The window of claim 9, wherein the dopant includes at least one of Ti, Co, Cr, Fe, and Cu.

11. The window of claim 1, further comprising:
an inorganic layer disposed between the substrate and the coating layer.

12. A display device comprising:
a display panel including at least one light emitting element;
a substrate disposed on the display panel;
at least one light control layer disposed on the substrate and, which controls light having a wavelength of about 280 nm or less; and
a coating layer disposed on the at least one light control layer.

13. The display device of claim 12, wherein the at least one light control layer includes:
at least one light absorption layer disposed on the substrate and, which absorbs the light having the wavelength of about 280 nm or less; and
at least one refractive layer disposed on the substrate.

14. The display device of claim 13, wherein the at least one light absorption layer includes at least one of benzotriazole, triazine, benzimidazole, ZnO, and TiO₂.

15. The display device of claim 13, wherein the at least one refractive layer includes at least one of MgF₂, CaF₂, BaF₂, LiF, and CeF₃.

16. The display device of claim 13, wherein a thickness of each of the at least one refractive layer is about 50 nm to about 100 nm.

17. The display device of claim 12, wherein the substrate is a sapphire substrate.

18. The display device of claim 17, wherein the sapphire substrate is doped with a dopant.

19. The display device of claim 18, wherein the dopant includes at least one of Ti, Co, Cr, Fe, and Cu.

20. The display device of claim 12, further comprising:
an inorganic layer disposed between the substrate and the coating layer.

21. The display device of claim 12, further comprising:
an adhesive layer disposed between the display panel and the substrate.
